(19) United States
(12) Patent Application Publication
(10) Pub. No.: US 2019/0006490 A1
(43) Pub. Date: Jan. 3, 2019

(54) THIN FILM TRANSISTOR AND METHOD FOR FABRICATING THE SAME, DISPLAY DEVICE, EXPOSURE DEVICE

(71) Applicants: BOE TECHNOLOGY GROUP CO., LTD., Beijing (CN); CHONGQING BOE OPTOELECTRONICS TECHNOLOGY CO., LTD., Chongqing (CN)

(72) Inventors: Zhuo XU, Beijing (CN); Ming DENG, Beijing (KR); Zhihui WANG, Beijing (CN); Xiuzhu TANG, Beijing (CN); Shuai CHEN, Beijing (CN); Zhenguo TIAN, Beijing (CN); Keguo LIU, Beijing (CN); Yanli ZHAO, Beijing (CN)

(21) Appl. No.: 15/952,590

(22) Filed: Apr. 13, 2018

(30) Foreign Application Priority Data
Jun. 28, 2017 (CN) 201710512269.1

(51) Int. Cl. H01L 29/66; H01L 21/02; H01L 21/027; H01L 21/306; H01L 21/308; H01L 29/786; H01L 27/12; G03F 1/38; G03F 7/16; G03F 7/20; G03F 7/30; G03F 7/40; G03F 7/09

(52) U.S. Cl. CPC H01L 29/66765; G03F 7/70058; H01L 21/02532; H01L 21/0262; H01L 21/0274; H01L 21/30604; H01L 21/308; H01L 29/78696; H01L 29/78669; H01L 27/127; H01L 27/1288; H01L 27/1222; G03F 1/38; G03F 7/16; G03F 7/20; G03F 7/30; G03F 7/40; G03F 7/094; G03F 7/168; H01L 21/02592

(57) ABSTRACT

A thin film transistor, a method for fabricating the same, a display device, and an exposure device are disclosed. The method comprises: patterning a source and drain layer by using a single slit mask and an exposure machine, to form a source, a drain, and an active region of the thin film transistor; wherein a pattern resolution of the single slit mask is not larger than a resolution of the exposure machine to form a groove shaped exposure pattern, wherein the groove shaped exposure pattern corresponds to the active region.

### RELATED APPLICATIONS

The present application claims the benefit of Chinese Patent Application No. 201710512269.1, filed on Jun. 28, 2017, the entire disclosure of which is incorporated herein by reference.

### TECHNICAL FIELD

The present disclosure relates to the field of thin film transistors, and particularly to a thin film transistor, a method for fabricating the same, a display device, and an exposure device.

### BACKGROUND

The characteristics of a thin film transistor (TFT) play a key role on a charging rate of a display device. Endeavors have been made to miniaturization of the TFT and improvement in its On-state current (Ion) in the art. A small size display device generally requires a low power consumption and high transmittance, which imminently requires reduce the size of TFT by developing new narrow channel techniques. The oxide thin film transistor (Oxide TFT) technology is not mature yet, and the low temperature poly-silicon thin film transistor (LTPS TFT) is costly so that it can not be applied to a production line of a high generation. Currently, amorphous silicon (a-Si) is used in an active layer of TFT in most display device. TFTs resulting from this method comprise an active region which has a length generally larger than 3.5 μm. The active region indicates a channel region for carriers, which is formed on a surface region of the active layer between a source and a drain of the TFT during operation. As a result, the channel region has a large length, and has a poor process stability which is strongly dependent on fabricating apparatuses.

### SUMMARY

In a first aspect, it is provided a method for fabricating a thin film transistor, comprising: patterning a source and drain layer by using a single slit mask (SSM) and an exposure machine, to form a source, a drain, and an active region of the thin film transistor; wherein a pattern resolution of the single slit mask is not larger than a resolution of the exposure machine to form a groove shaped exposure pattern, wherein the groove shaped exposure pattern corresponds to the active region.

In an exemplary embodiment, the step of patterning the source and drain layer by using the single slit mask and the exposure machine, to form the source, the drain, and the active region of the thin film transistor comprises: coating a first photoresist on the source and drain layer; exposing and developing the first photoresist by using the single slit mask and the exposure machine according to a size of the source and the drain, so that the resulting first photoresist on the source and drain layer forms a groove shaped exposure pattern; ashing the first photoresist at a bottom of the groove shaped exposure pattern, to reveal the source and drain layer; wet etching the source and drain layer to form the source and the drain, and to reveal an active layer at a position to which the groove shaped exposure pattern corresponds to form the active region of the thin film transistor; and removing the remaining first photoresist.

In an exemplary embodiment, the ashing is performed for a duration of about 25˜100 seconds.

In an exemplary embodiment, the ashing is performed at a temperature of about 25˜60° C.

In an exemplary embodiment, an acid etching solution is used for wet etching the source and drain layer.

In an exemplary embodiment, prior to patterning the source and drain layer by using the single slit mask and the exposure machine, the method further comprises: forming an active layer on a substrate; forming a source and drain layer on the substrate and the active layer; wherein edges of an orthographic projection of the active layer on the substrate are aligned with edges of an orthographic projection of the source and the drain of the thin film transistor.

In an exemplary embodiment, forming the active layer on the substrate comprises: forming an amorphous silicon layer on the substrate; coating a second photoresist on the amorphous silicon layer; exposing and developing the second photoresist by using a mask; etching the amorphous silicon layer to form the active layer; and removing the remaining second photoresist.

In an exemplary embodiment, prior to patterning the source and drain layer by using the single slit mask and the exposure machine, the method further comprises: forming an active layer on a substrate; forming transition layer on the active layer; and forming the source and drain layer on the substrate and the transition layer, wherein edges of an orthographic projection of the active layer on the substrate are aligned with edges of an orthographic projection of the source and the drain of the thin film transistor.

In an exemplary embodiment, the step of wet etching the source and drain layer to form the source and the drain, and to reveal an active layer at a position to which the groove shaped exposure pattern corresponds to form the active region of the thin film transistor comprises: wet etching the source and drain layer to form the source and the drain, and to reveal the transition layer at a position to which the groove shaped exposure pattern corresponds; and dry etching the transition layer, to reveal the active layer to form the active region of the thin film transistor.

In an exemplary embodiment, the transition layer comprises phosphor doped amorphous silicon.

In an exemplary embodiment, the phosphor doped amorphous silicon is formed by using PH₃ and SiH₄ with a volume ratio about 2:1˜3:1.

In an exemplary embodiment, a duration for dry etching the transition layer is about 15˜30 seconds.

In a second aspect, it is provided a thin film transistor, wherein the thin film transistor comprises a active region which has a length not larger than 3.5 μm.

In an exemplary embodiment, edges of an orthographic projection of the active layer on the substrate are aligned with edges of an orthographic projection of the source and the drain of the thin film transistor.

In a third aspect, it is provided a display device, comprising the thin film transistor as described above.

In a fourth aspect, it is provided an exposure device, comprising an exposure machine and a single slit mask, wherein a pattern resolution of the single slit mask is not larger than a resolution of the exposure machine.

### BRIEF DESCRIPTION OF THE DRAWINGS

In order to explain the technical solutions in the embodiments of the present disclosure or the prior art more clearly, the drawings to be used in the description of the embodiments or the prior art will be introduced briefly in the following, apparently, the drawings described below are only some embodiments of the present disclosure, the ordinary skilled person in the art, on the premise of not paying any creative work, can also obtain other drawings from these drawings.

FIG. 1 is a flow chart for illustrating a method for fabricating a thin film transistor in an embodiment of the present disclosure;

FIGS. 2a, 2b, 2c and 2d are structural views for illustrating a thin film transistor at different fabricating stages in an embodiment of the present disclosure;

FIG. 3 is a flow chart for illustrating a method for fabricating a thin film transistor in an embodiment of the present disclosure;

FIGS. 4a, 4b, 4c, 4d, 4e, 4f, 4g, 4h, and 4i are structural views for illustrating a thin film transistor at different fabricating stages in an embodiment of the present disclosure;

FIG. 5 is a flow chart for illustrating steps for forming an active layer in an embodiment of the present disclosure;

FIG. 6 is a flow chart for illustrating a method for fabricating a thin film transistor in an embodiment of the present disclosure;

FIGS. 7a, 7b, 7c, 7d, 7e, 7f, 7g, 7h, 7i, 7j, 7k are structural views for illustrating a thin film transistor at different fabricating stages in an embodiment of the present disclosure; and

FIG. 8 is a flow chart for illustrating steps for forming a source, a drain and an active region of a thin film transistor in an embodiment of the present disclosure.

### DETAILED DESCRIPTION OF EMBODIMENTS

To make the objects, the technical solutions and the advantages of embodiments of the present disclosure more apparent, the technical solutions of the embodiments of the present disclosure will be described in detail hereinafter in conjunction with the drawings of the embodiments of the present disclosure. Apparently, the embodiments described hereinafter are only some embodiments of the present disclosure, but not all embodiments. Based the embodiments described hereinafter, other embodiments obtained by those skilled in the art should fall within the scope of the present disclosure.

Embodiments of the present disclosure provide a thin film transistor, a method for fabricating the same, a display device, and an exposure device, to solve the problem in which a thin film transistor with a narrow channel region is difficult to fabricate.

An embodiment of the present disclosure provides a method for fabricating a thin film transistor. The method comprises: patterning a source and drain layer by using a single slit mask and an exposure machine, to form a source, a drain, and an active region of the thin film transistor.

A pattern resolution of the single slit mask is not larger than a resolution of the exposure machine to form a groove shaped exposure pattern. The groove shaped exposure pattern corresponds to the active region. For example, the pattern resolution of the single slit mask can be smaller than the resolution of the exposure machine by 2 μm. Thus, the resulting active region (i.e., channel region) is short, with a length not larger than 3.5 μm. This can improve the On-state current and charging rate, and reduce the size of the thin film transistor.

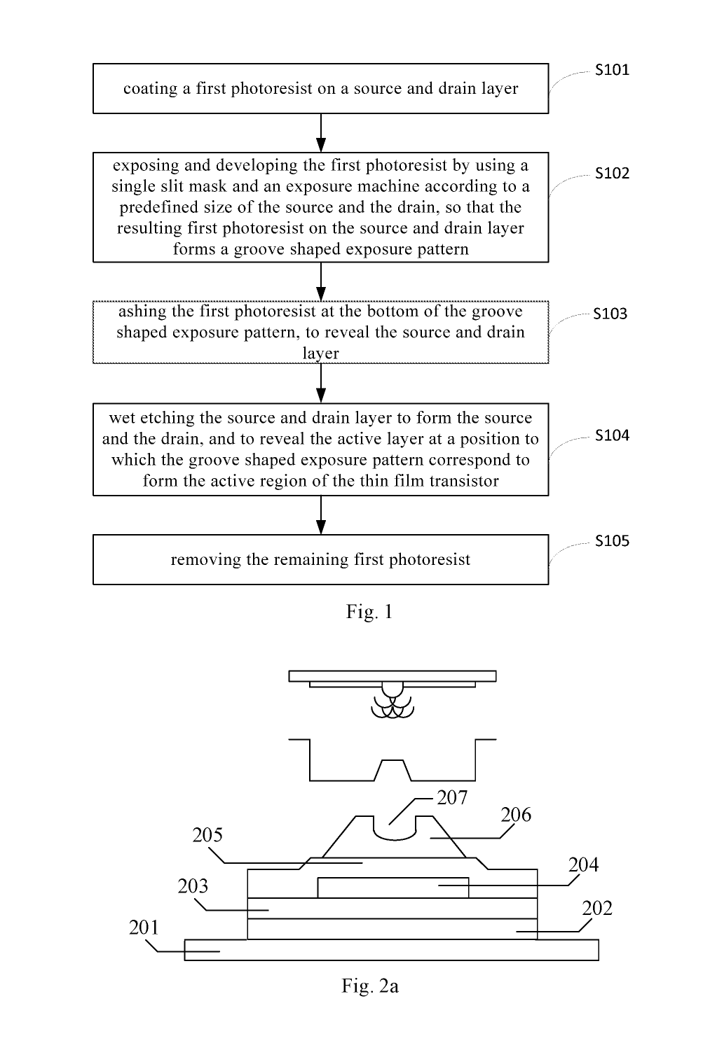

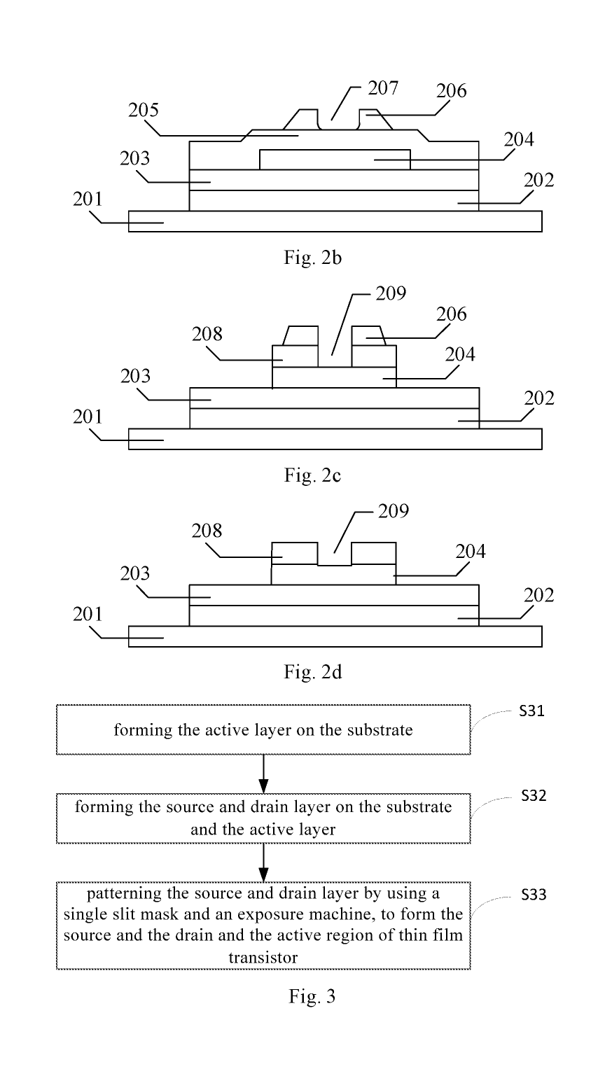

As shown in FIG. 1 and FIGS. 2a-2d, the method comprises the following steps.

Step S101: coating a first photoresist 206 on a source and drain layer 205.

This step is conducted at room temperature and atmospheric pressure. After coating, the first photoresist 206 needs baking.

It is noted that, prior to this step, a gate 202, an insulating layer 203, an active layer 204 and the source and drain layer 205 have been formed on a substrate 201 which are stacked in this order.

Step S102: exposing and developing the first photoresist 206 by using a single slit mask and an exposure machine according to a predefined size of the source and the drain 208, so that the resulting first photoresist 206 on the source and drain layer 205 forms a groove shaped exposure pattern 207.

As shown in FIG. 2a, in this step, the resulting first photoresist 206 on the source and drain layer 205 forms the groove shaped exposure pattern 207 due to under exposure. The groove shaped exposure pattern 207 generally reduces its width from an opening to a bottom, and for example has a U shaped cross-section. During development with a developing solution, only the first photoresist 206 at the bottom of the groove shaped exposure pattern 207 can be removed. This facilitates forming subsequently an active region 209 with a small length.

Step S103: ashing the first photoresist 206 at the bottom of the groove shaped exposure pattern 207, to reveal the source and drain layer 205.

The purpose of ashing is to consume the first photoresist 206 by an oxidation reaction, so as to thin the first photoresist 206.

The ashing adopts vapor phase ashing. The ashing gases comprises: SF₆, O₂ and He. In particular, the volume ratio of SF₆, O₂ and He is 0.5˜2:30:0.5˜2. For example, the volume ratio of SF₆, O₂ and He is 1:30:1. The pressure of ashing gases is 50 mT˜200 mT. For example, the pressure of ashing gases is 100 mT.

The temperature for ashing is about 25˜60° C. The duration for ashing is about 25˜100 seconds. For example, the duration for ashing is 50 seconds. By controlling the duration for ashing, the thickness of the first photoresist 206 which is reduced can be controlled, and thus the of the subsequently formed active region 209 can be controlled.

As shown in FIG. 2b, by this step, the first photoresist 206 at the bottom of the groove shaped exposure pattern 207 is removed, and the source and drain layer 205 at the corresponding position is revealed. This facilitates subsequently etching the source and drain layer 205 at this position.

Step S104: wet etching the source and drain layer 205 to form the source and the drain 208, and to reveal the active layer 204 at a position to which the groove shaped exposure pattern 207 correspond to form the active region 209 of the thin film transistor.

In the wet etching, the etching solution is acid etching solution. The effective component in the acid etching solution comprises cations like H⁺, and anions like PO₄³⁻, Cl⁻, F⁻, NO₃⁻. The acid etching solution is formed by mixing a H₃PO₄ etching solution with other acid etching solutions in a molar concentration ratio of 7:1.

As shown in FIG. 2c, the first photoresist 206 acts as a blocking layer, so that a portion of the source and drain layer 205 which does not contact the acid etching solution is retained. By patterning through wet etching, this portion of the source and drain layer 205 forms the source and the drain 208. The remaining portion of the source and drain layer 205 is removed to reveal the active layer 204, and the active region 209 is formed between the source and the drain 208. Since the wet etching is conducted only once (for one time), this will not result in a large critical dimension bias (CD bias). For example, the active region 209 has a length smaller than a sum of the resolution size of the exposure machine and the CD bias of wet etching, i.e. not larger than 3.5 μm.

Step S105: removing the remaining first photoresist 206.

As shown in FIG. 2d, after the remaining first photoresist 206 is removed, the fabrication of thin film transistor is complete. The thin film transistor comprises the substrate 201, the gate 202, the insulating layer 203, the active layer 204, the source and the drain 208 which are stacked in this order. The active region 209 lies between the source and the drain 208.

The source and the drain 208 and the active region 209 are formed by the process as described above.

In short, embodiments of the present disclosure provide a method for fabricating a thin film transistor. A mask which has a pattern resolution not larger than a resolution of the exposure machine is used, and the active region 209 with a length not larger than 3.5 μm can be formed. This can improve the On-state current and the charging rate, and reduce the size of the thin film transistor.

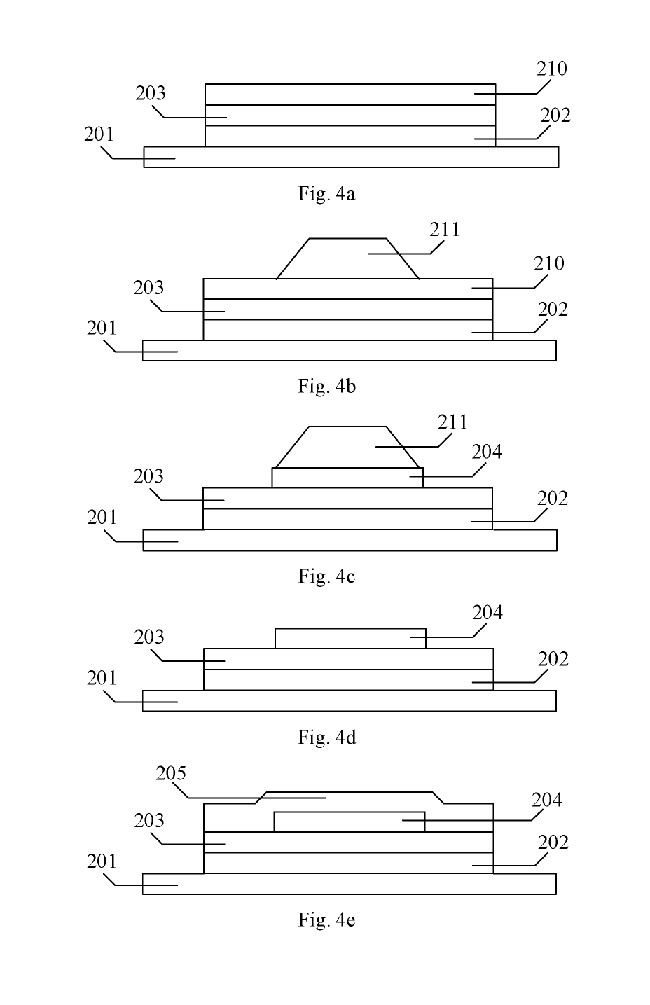

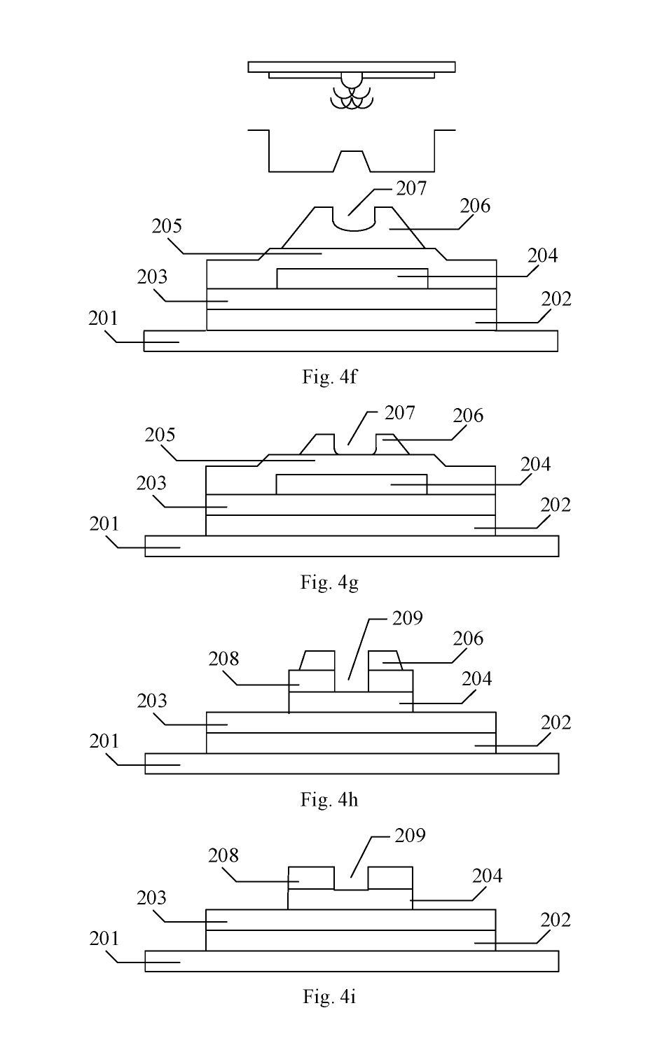

Embodiments of the present disclosure provide a method for fabricating a thin film transistor. In this embodiment, the active layer is formed separately from the source and the drain. As shown in FIG. 3 and FIGS. 4a-4i, the method comprises the following steps.

Step S31: forming the active layer 204 on the substrate 201.

Step S32: forming the source and drain layer 205 on the substrate 201 and the active layer 204.

Step S33: patterning the source and drain layer 205 by using a single slit mask and an exposure machine, to form the source and the drain 208 and the active region 209 of thin film transistor.

Step S33 is identical with the step of forming the source and the drain 208 and the active region 209 of the thin film transistor in the embodiment discussed with reference to FIG. 1 and FIGS. 2a-2d. Namely, a single slit mask with a pattern resolution not larger than a resolution of the exposure machine is used to form the groove shaped exposure pattern 207. A region of the source and drain layer 205 to which the groove shaped exposure pattern 207 corresponds forms the active region 209.

Thus, by applying the method as described above, the resulting thin film transistor comprises the active region 209 with a small length, which is similar with the thin film transistor in the embodiment of FIG. 1 and FIGS. 2a-2d. Thus, the same beneficial effects as the embodiment of FIG. 1 and FIGS. 2a-2d are obtained. In addition, in the fabricating method of FIG. 3 and FIGS. 4a-4i, the active layer 204 and the source and the drain 208 are formed separately. Namely, the active layer 204 and the source and the drain 208 are exposed and etched separately, so that the processes for them will not interference with one another. Edges of an orthographic projection of the active layer 204 on the substrate 201 are aligned with edges of an orthographic projection of the source and the drain 208 on the substrate 201, so that there is no residual of the active layer 204.

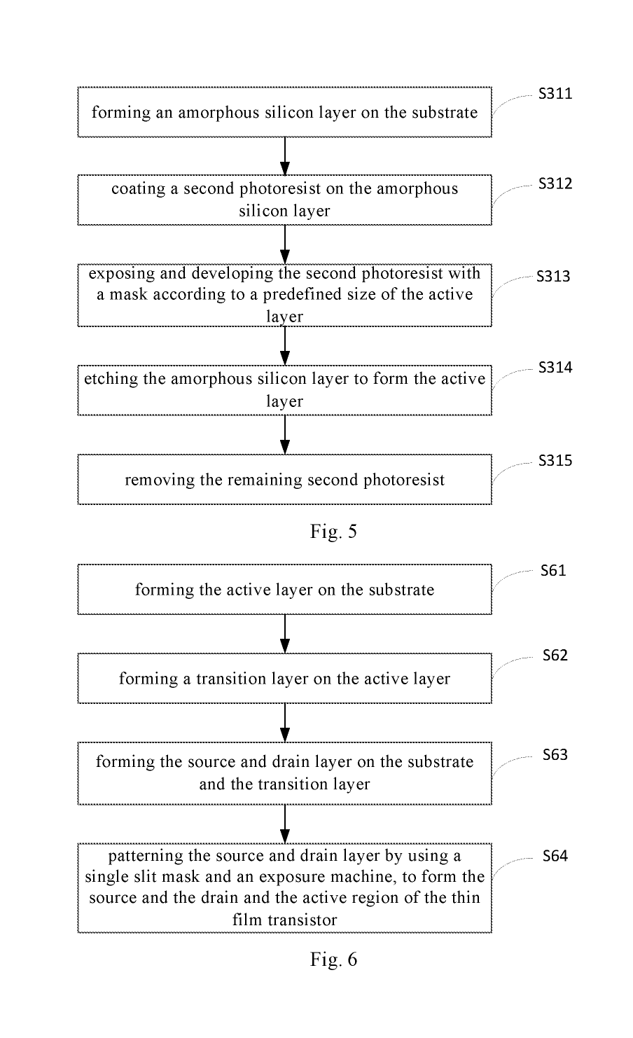

In particular, as shown in FIGS. 4a-4i and FIG. 5, step S31 comprises the followings steps.

Step S311: forming an amorphous silicon layer 210 on the substrate 201.

In particular, as shown in FIG. 4a, the amorphous silicon layer 210 can be deposited by plasma enhanced chemical vapor deposition (PECVD). SiH₄, NH₃ and N₂ are used as the precursor gases. They are mixed at a certain volume ratio, and react at temperature of about 300° C.˜400° C. and a power of about 1˜4 kW (e.g., 2 kW), to form the amorphous silicon layer 210 on the substrate 201. For example, the volume ratio of SiH₄, NH₃ and N₂ is 1:5:16. During deposition, the duration of deposition can be controlled to obtain the required thickness of the amorphous silicon layer 210.

Step S312: coating a second photoresist 211 on the amorphous silicon layer 210.

As shown in FIG. 4b, this step is conducted at a room temperature and an atmospheric pressure. After coating, the second photoresist 211 needs baking.

Step S313: exposing and developing the second photoresist 211 with a mask according to a predefined size of the active layer 204.

This step is conducted at a room temperature and an atmospheric pressure. As shown in FIG. 4b, in this step, the second photoresist 211 is exposed and developed in certain regions according to the predefined size of the active layer 204.

Step S314: etching the amorphous silicon layer 210 to form the active layer 204.

The etching can adopt dry etching, such as ICP (Inductively Coupled Plasma) and ECCP (Enhance Cathode Couple Plasma). In this step, SF₆ and Cl₂ of a certain volume ratio are used as the reaction gases, and dry etching is conducted at a room temperature and a low vacuum environment. In particular, the volume ratio of SF₆ and Cl₂ can be about 0.5˜2:8, e.g., 1:8. The duration for etching can be selected according to the required thickness of the active layer 204. Generally, the etching duration for the active layer 204 with a thickness of 200 nm is about 45˜60 seconds.

As shown in FIG. 4c, in this step, the amorphous silicon layer 210 is patterned to form the active layer 204.

Step S315: removing the remaining second photoresist 211.

As shown in FIG. 4d, in particular, an organic solvent can be used to dissolve the second photoresist 211 in a wet way. Also, vapor phase reaction (for example UN-ozone) can be applied to etch the second photoresist 211 in a dry way, so as to remove the second photoresist 211.

The active layer 204 can be completed with the above steps.

In particular, as shown in FIG. 4e, the source and drain layer 205 is formed by sputtering or other methods for forming metallic films in step S32. An orthographic projection of the active layer 204 on the substrate 201 falls within an orthographic projection of the source and drain layer 205 on the substrate 201.

In particular, as shown in FIG. 4f˜FIG. 4i, step S33 is completely identical with steps for forming the source, the drain and the active region as shown in FIG. 1 and FIGS. 2a-2d, which is not repeated here for simplicity.

In short, in the method for fabricating a thin film transistor shown in FIG. 3 and FIGS. 4a-4i, the mask with the pattern resolution not larger than the resolution of the exposure machine is adopted. The active region 209 with a length not larger than 3.5 μm can be formed. This can improve the On-state current and charging rate, and reduce the size of the thin film transistor. In addition, edges of an orthographic projection of the active layer 204 on the substrate 201 are aligned with edges of an orthographic projection of the source and the drain 208 on the substrate 201, so that there is no residual of the active layer 204. This can significantly reduce load and increase charging rate. Further, this can reduce a line width of the gate 202 and the source and the drain 208, and increase aperture ratio.

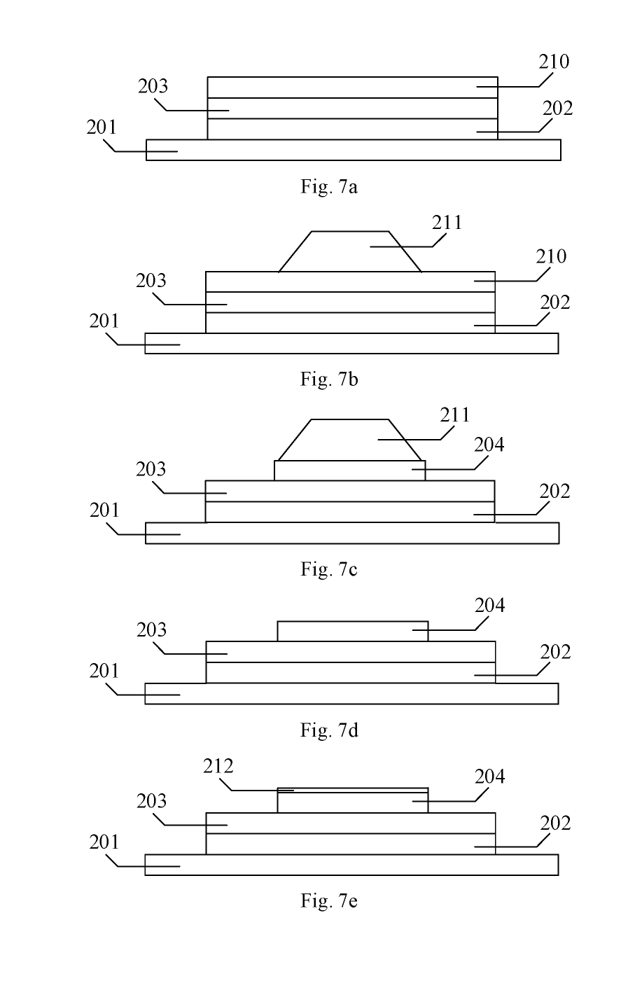

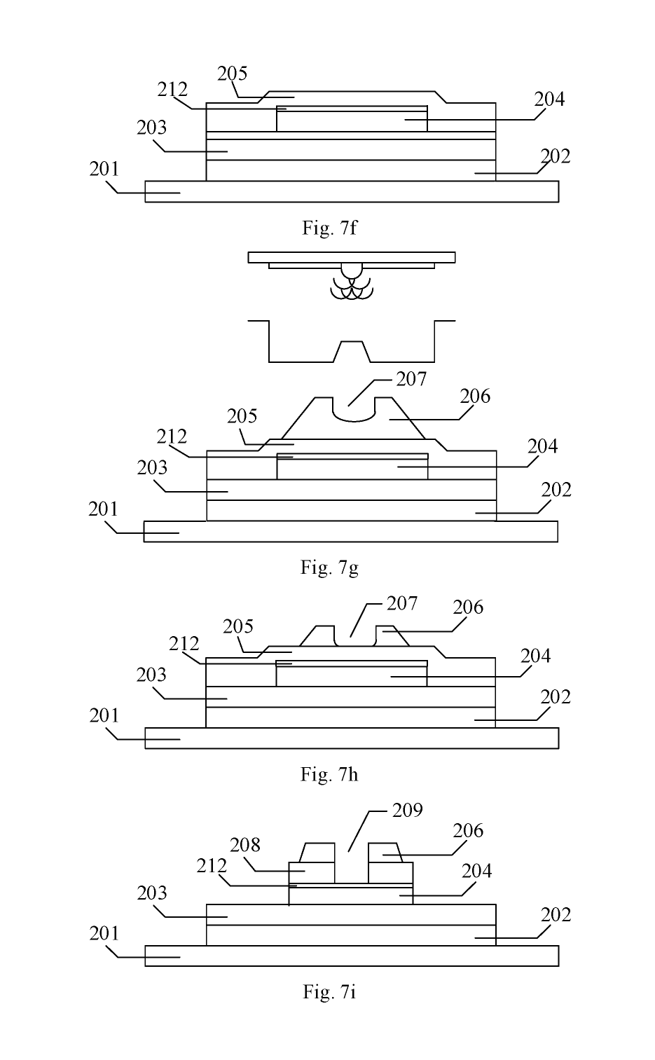

An embodiment of the present disclosure provides a method for fabricating a thin film transistor. The present embodiment differs from the method of FIG. 3 and FIGS. 4a-4i in that, the present embodiment further comprises a step of forming a transition layer. As shown in FIG. 6 and FIGS. 7a-7k, the fabricating method comprises the following steps.

Step S61: forming the active layer 204 on the substrate 201.

As shown in FIG. 7a˜FIG. 7d, this step is identical with step S31 in FIG. 3 and FIGS. 4a-4i, which is not repeated here for simplicity.

Step S62: forming a transition layer 212 on the active layer 204.

This step is shown in FIG. 7e. The transition layer 212 comprises phosphor doped amorphous silicon. PH₃ and SiH₄ with a volume ratio about 2:13:1 are used to form the phosphor doped amorphous silicon. The transition layer 212 functions to increase the electrical conductivity.

Step S63: forming the source and drain layer 205 on the substrate 201 and the transition layer 212.

As shown in FIG. 7f, this step is identical with step S32 in FIG. 3 and FIGS. 4a-4i, which is not repeated here for simplicity. The difference lies in that the source and drain layer 205 are formed on the substrate 201 and the transition layer 212.

Step S64: patterning the source and drain layer 205 by using a single slit mask and an exposure machine, to form the source and the drain 208 and the active region 209 of the thin film transistor.

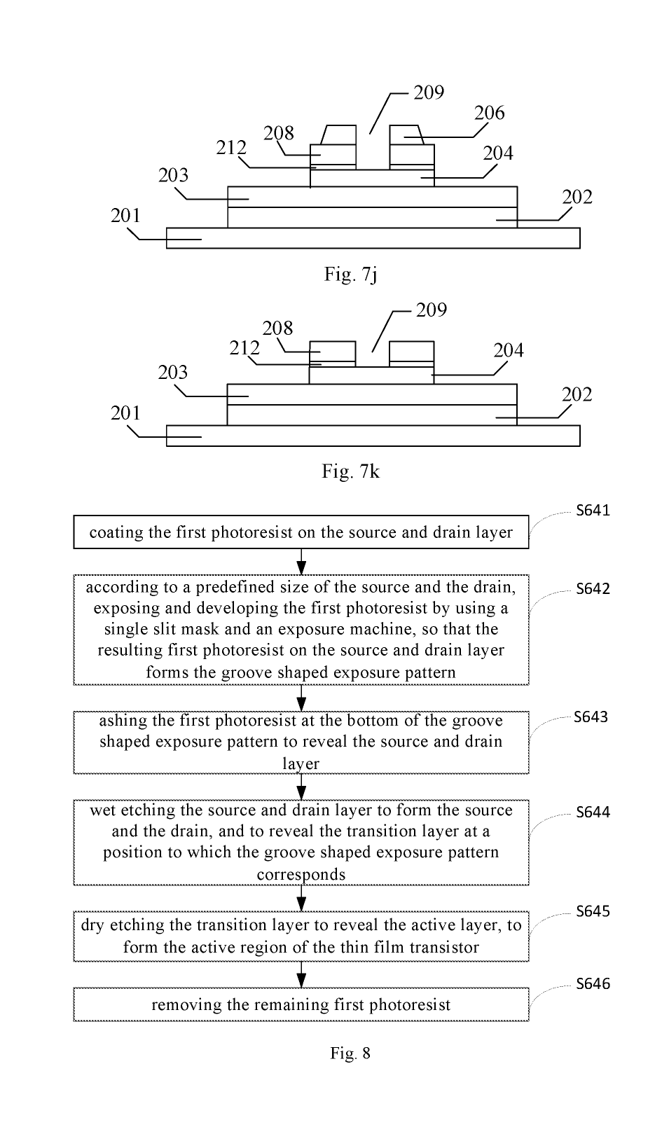

In step S62, the transition layer 212 is additionally formed. Thus, as shown in FIG. 8 and FIG. 7g˜FIG. 7k, step S64 specifically comprises the following steps.

Step S641: coating the first photoresist 206 on the source and drain layer 205.

Step S642: according to a predefined size of the source and the drain 208, exposing and developing the first photoresist 206 by using a single slit mask and an exposure machine, so that the resulting first photoresist 206 on the source and drain layer 205 forms the groove shaped exposure pattern 207.

Step S643: ashing the first photoresist 206 at the bottom of the groove shaped exposure pattern 207 to reveal the source and drain layer 205.

Step S644: wet etching the source and drain layer 205 to form the source and the drain 208, and to reveal the transition layer 212 at a position to which the groove shaped exposure pattern 207 corresponds.

As shown in FIG. 7i, in this step, the transition layer 212 is revealed at a position to which the groove shaped exposure pattern 207 corresponds.

Step S645: dry etching the transition layer 212 to reveal the active layer 204, to form the active region 209 of the thin film transistor.

As shown in FIG. 7j, in this step, the active layer 204 is revealed.

The dry etching method can be ICP or ECCP. The duration for dry etching the transition layer 212 is about 15˜30 seconds. By controlling the duration for dry etching the transition layer 212, it is possible to prevent the active layer 204 from being etched.

The gases for dry etching the transition layer 212 comprise SF₆ and Cl₂, and dry etching is conducted at a room temperature and a low vacuum environment. In particular, the volume ratio of SF₆ and Cl₂ is about 0.5˜2:8, e.g., 1:8.

Step S646: removing the remaining first photoresist 206.

In the above steps S641˜S646, other processes than the process of dry etching the transition layer 212 comprise the same parameters as step S33 in FIG. 3 and FIGS. 4a-4i, which are not repeated here for simplicity.

With the above steps, the source and the drain 208 and the active region 209 are formed.

In short, in the method for fabricating a thin film transistor of the present embodiment, the mask with the pattern resolution not larger than the resolution of the exposure machine is adopted. The active region 209 with a length not larger than 3.5 μm can be formed. This can improve the On-state current and charging rate, and reduce the size of the thin film transistor. In addition, edges of an orthographic projection of the active layer 204 on the substrate 201 are aligned with edges of an orthographic projection of the source and the drain 208 on the substrate 201, so that there is no residual of the active layer 204. This can significantly reduce load and increase charging rate. Further, this can reduce a line width of the gate 202 and the source and the drain 208, and increase aperture ratio.

An embodiment of the present disclosure provides a thin film transistor. The thin film transistor is formed by the method described in the embodiment of FIG. 1 and FIGS. 2a-2d, the embodiment of FIG. 3 and FIGS. 4a-4i, or the embodiment of FIG. 6 and FIG. 7a-7k.

As shown in FIG. 2d, 4i or 7k, in the thin film transistor, the active region 209 has a length not larger than 3.5 μm. Thus, the active region 209 of the thin film transistor is narrow.

For example, edges of an orthographic projection of the active layer 204 on the substrate 201 are aligned with edges of an orthographic projection of the source and the drain 208 on the substrate 201. Thus, there is no residual of the active layer 204 in the thin film transistor.

In short, in the thin film transistor of the present embodiment, edges of an orthographic projection of the active layer 204 on the substrate 201 are aligned with edges of an orthographic projection of the source and the drain 208 on the substrate 201, so that there is no residual of the active layer 204. This can significantly reduce load, and increase charging rate. Further, this can reduce the line width of the gate 202 and the source and the drain 208, and increase the aperture ratio. The active region 209 has a length not larger than 3.5 μm, which can improve the On-state current and charging rate, and reduce the size of the thin film transistor.

An embodiment of the present disclosure provides a display device. The display device comprises the thin film transistor as described in the above embodiments.

The display device comprises the thin film transistor of the above embodiments. There is no residual of the active layer. This can significantly reduce load, and increase charging rate. Further, this can reduce the line width of the gate, source and drain, and increase aperture ratio. The active region 209 has a length not larger than 3.5 μm, which can improve the On-state current and charging rate, and reduce the overall size of the thin film transistor.

An embodiment of the present disclosure provides an exposure device. In particular, the exposure device comprises an exposure machine and a single slit mask. The single slit mask has a pattern resolution which is not larger than a resolution of the exposure machine.

The exposure device can be used to fabricate a thin film transistor with a narrow active region, so that the active region has a length not larger than 3.5 μm. This can improve the On-state current and charging rate, and reduce the size of the thin film transistor.

Apparently, the person with ordinary skill in the art can make various modifications and variations to the present disclosure without departing from the spirit and the scope of the present disclosure. In this way, provided that these modifications and variations of the present disclosure belong to the scopes of the claims of the present disclosure and the equivalent technologies thereof, the present disclosure also intends to encompass these modifications and variations.

What is claimed is:

1. A method for fabricating a thin film transistor, comprising:
patterning a source and drain layer by using a single slit mask and an exposure machine, to form a source, a drain, and an active region of the thin film transistor;
wherein a pattern resolution of the single slit mask is not larger than a resolution of the exposure machine to form a groove shaped exposure pattern, wherein the groove shaped exposure pattern corresponds to the active region.

2. The method of claim 1, wherein the step of patterning the source and drain layer by using the single slit mask and the exposure machine, to form the source, the drain, and the active region of the thin film transistor comprises:
coating a first photoresist on the source and drain layer;
exposing and developing the first photoresist by using the single slit mask and the exposure machine according to a size of the source and the drain, so that the resulting first photoresist on the source and drain layer forms a groove shaped exposure pattern;
ashing the first photoresist at a bottom of the groove shaped exposure pattern, to reveal the source and drain layer;
wet etching the source and drain layer to form the source and the drain, and to reveal an active layer at a position to which the groove shaped exposure pattern corresponds to form the active region of the thin film transistor; and
removing the remaining first photoresist.

3. The method of claim 2, wherein the ashing is performed for a duration of about 25˜100 seconds.

4. The method of claim 2, wherein the ashing is performed at a temperature of about 25˜60° C.

5. The method of claim 2, wherein an acid etching solution is used for wet etching the source and drain layer.

6. The method of claim 1, wherein prior to patterning the source and drain layer by using the single slit mask and the exposure machine, the method further comprises:
forming an active layer on a substrate;
forming a source and drain layer on the substrate and the active layer;
wherein edges of an orthographic projection of the active layer on the substrate are aligned with edges of an orthographic projection of the source and the drain of the thin film transistor.

7. The method of claim 6, wherein forming the active layer on the substrate comprises:
forming an amorphous silicon layer on the substrate;
coating a second photoresist on the amorphous silicon layer;
exposing and developing the second photoresist by using a mask;
etching the amorphous silicon layer to form the active layer; and
removing the remaining second photoresist.

8. The method of claim 2, wherein prior to patterning the source and drain layer by using the single slit mask and the exposure machine, the method further comprises:
forming an active layer on a substrate;
forming transition layer on the active layer; and
forming the source and drain layer on the substrate and the transition layer,
wherein edges of an orthographic projection of the active layer on the substrate are aligned with edges of an orthographic projection of the source and the drain of the thin film transistor.

9. The method of claim 8, wherein the step of wet etching the source and drain layer to form the source and the drain, and to reveal an active layer at a position to which the groove shaped exposure pattern corresponds to form the active region of the thin film transistor comprises:
wet etching the source and drain layer to form the source and the drain, and to reveal the transition layer at a position to which the groove shaped exposure pattern corresponds; and
dry etching the transition layer, to reveal the active layer to form the active region of the thin film transistor.

10. The method of claim 9, wherein the transition layer comprises phosphor doped amorphous silicon.

11. The method of claim 10, wherein the phosphor doped amorphous silicon is formed by using PH₃ and SiH₄ with a volume ratio about 2:1˜3:1.

12. The method of claim 9, wherein a duration for dry etching the transition layer is about 15˜30 seconds.

13. A thin film transistor, wherein the thin film transistor comprises an active region which has a length not larger than 3.5 μm.

14. The thin film transistor of claim 13, wherein edges of an orthographic projection of the active layer on the substrate are aligned with edges of an orthographic projection of the source and the drain of the thin film transistor.

15. A display device, comprising the thin film transistor of claim 14.

16. An exposure device, comprising an exposure machine and a single slit mask, wherein a pattern resolution of the single slit mask is not larger than a resolution of the exposure machine.
